(19) United States
(12) Patent Application Publication
(10) Pub. No.: US 2024/0258440 A1
(43) Pub. Date: Aug. 1, 2024

(54) MULTILAYER ANTIREFLECTION COATINGS ON TEXTURED SURFACE FOR BACK ILLUMINATED SILICON PHOTOMULTIPLIER

(71) Applicant: Georgia Tech Research Corporation, Atlanta, GA (US)

(72) Inventors: Yuguo Tao, Atlanta, GA (US); Anna S. Erickson, Atlanta, GA (US)

(21) Appl. No.: 18/408,102

(22) Filed: Jan. 9, 2024

Related U.S. Application Data
(60) Provisional application No. 63/479,248, filed on Jan. 10, 2023.

(51) Int. Cl. H01L 31/0216; H01L 31/0236; H01L 31/107

(52) U.S. Cl. CPC H01L 31/02161; H01L 31/02366; H01L 31/107

(57) ABSTRACT

An exemplary embodiment of the present disclosure provides a photomultiplier, comprising a silicon substrate, a first antireflective layer, and a second antireflective layer. The silicon substrate can have a top surface. The first anti-reflective layer can be disposed on the top surface of the silicon substrate. The second anti-reflective layer can be disposed on top of the first anti-reflective layer.

### CROSS-REFERENCE TO RELATED APPLICATIONS

This application claims the benefit of U.S. Provisional Application Ser. No. 63/479,248, filed on 10 Jan. 2023, which is incorporated herein by reference in its entirety as if fully set forth below.

### GOVERNMENT LICENSE RIGHTS

This invention was made with government support under Agreement No. DENA0003921, awarded by National Nuclear Security Administration. The government has certain rights in the invention.

### FIELD OF THE DISCLOSURE

The various embodiments of the present disclosure relate generally to photomultipliers, and more specifically to antireflective coatings for photomultipliers.

### BACKGROUND

Silicon photomultipliers (SiPM) are the cornerstones of photodetector technologies for detecting faint light in both industry and scientific research since their early development in 1990s. Their attractive performances have brought benefits into emerging applications, such as ionizing radiation detection, biomedical imaging, and light detection and ranging (LiDAR) for autonomous driving. Compared to photomultiplier tube (PMT) that is a conventional photodetector legacy technology in the radiation detection, SiPM offers several advantages, including low operation voltage, compactness, ruggedness, and relatively low cost. Furthermore, in contrast to PMT, SiPM is insensitive to magnetic fields, which leads to its vital role as the foundation of light detection technology for the advanced medical equipment in the presence of magnetic fields, such as positron emission tomography (PET) imaging. However, the photon detection efficiency (PDE) that is defined as the ratio between the numbers of detected photons and the photons arriving at the detector, which is also one of the key measurable metrics that quantify SiPM's performance, is still limited to about 60% and rapidly decreases from the peak as the wavelength enters into the ultraviolet range. This is due to not only the reflection losses of photons impinging on the front planar silicon surface, but also the limited fill factor (FF) caused by the dead areas (i.e., quenching resistor, isolation trench, guard ring, and contact metal) for the conventional front-illuminated structure, in addition to the recombination loss of the photo-generated primary carriers near defect centers. Therefore, a reduction in photon reflection at the surface is a prominent role in the development of high-performance SiPM devices. Accordingly, there is a need for photomultipliers with improved antireflective properties.

### BRIEF SUMMARY

An exemplary embodiment of the present disclosure provides a back-illuminated photomultiplier, comprising a silicon substrate, a first anti-reflective layer, and a second anti-reflective layer. The silicon substrate can have a top surface. The first anti-reflective layer can be disposed on the top surface of the silicon substrate. The second anti-reflective layer can be disposed on a top surface of the first anti-reflective layer.

In any of the embodiments disclosed herein, one of the first and second anti-reflective layers can comprise MgF₂.

In any of the embodiments disclosed herein, one of the first and second anti-reflective layers can comprise ZnS.

In any of the embodiments disclosed herein, the photomultiplier can further comprise a third anti-reflective layer disposed on a top surface of the second anti-reflective layer.

In any of the embodiments disclosed herein, one of the first, second, and third anti-reflective layers can comprise MgF₂.

In any of the embodiments disclosed herein, one of the first, second, and third anti-reflective layers can comprise HfO₂.

In any of the embodiments disclosed herein, one of the first, second, and third anti-reflective layers can comprise TiO₂.

In any of the embodiments disclosed herein, the top surface of the silicon substrate can comprise a plurality of protrusions extending upwards from the top surface.

In any of the embodiments disclosed herein, the plurality of protrusions can be pyramid-shaped.

In any of the embodiments disclosed herein, the plurality of protrusions can have non-uniform sizes.

In any of the embodiments disclosed herein, the photomultiplier can reflect less than 15% of photons incident on the photomultiplier averaged across a wavelength range of 200 nm-800 nm.

In some of the embodiments disclosed herein, the photomultiplier can reflect less than 13% of photons incident on the photomultiplier averaged across a wavelength range of 200 nm-800 nm.

In some of the embodiments disclosed herein, the photomultiplier can reflect less than 7% of photons incident on the photomultiplier averaged across a wavelength range of 200 nm-800 nm.

In some of the embodiments disclosed herein, the photomultiplier can reflect less than 5% of photons incident on the photomultiplier averaged across a wavelength range of 200 nm-800 nm.

In some of the embodiments disclosed herein, the photomultiplier can reflect less than 3% of photons incident on the photomultiplier averaged across a wavelength range of 200 nm-800 nm.

Another embodiment of the present disclosure provides a back-illuminated photomultiplier, comprising a silicon substrate and a first anti-reflective layer. The silicon substrate can have a top surface comprising a plurality of non-uniform protrusions. The first anti-reflective layer can be disposed on the top surface of the silicon substrate.

In any of the embodiments disclosed herein, the photomultiplier can further comprise a second anti-reflective layer disposed on the top surface of the first anti-reflective layer.

In any of the embodiments disclosed herein, the photomultiplier can further comprise a third anti-reflective layer disposed on the top surface of the second anti-reflective layer.

These and other aspects of the present disclosure are described in the Detailed Description below and the accompanying drawings. Other aspects and features of embodiments will become apparent to those of ordinary skill in the art upon reviewing the following description of specific, exemplary embodiments in concert with the drawings. While features of the present disclosure may be discussed relative to certain embodiments and figures, all embodiments of the present disclosure can include one or more of the features discussed herein. Further, while one or more embodiments may be discussed as having certain advantageous features, one or more of such features may also be used with the various embodiments discussed herein. In similar fashion, while exemplary embodiments may be discussed below as device, system, or method embodiments, it is to be understood that such exemplary embodiments can be implemented in various devices, systems, and methods of the present disclosure.

### BRIEF DESCRIPTION OF THE DRAWINGS

The following detailed description of specific embodiments of the disclosure will be better understood when read in conjunction with the appended drawings. For the purpose of illustrating the disclosure, specific embodiments are shown in the drawings. It should be understood, however, that the disclosure is not limited to the precise arrangements and instrumentalities of the embodiments shown in the drawings.

FIGS. 1A and 1B provide schematics of a back-illuminated photomultiplier having a planar silicon substrate and double ARC (FIG. 1A) and triple ARC (FIG. 1B), in accordance with some embodiments of the present disclosure.

FIGS. 2A-C provide schematics of a back-illuminated photomultiplier having a textured silicon substrate with a single ARC (FIG. 2A), double ARC (FIG. 2B), and triple ARC (FIG. 2C), in accordance with some embodiments of the present disclosure.

FIGS. 3A-D provide schematics of various ARC features on silicon wafers, including no ARC (FIG. 3A), single-layer ARC (FIG. 3B), double-layer ARC (FIG. 3C), and triple-layer ARC (FIG. 3D), in which refractive indices of different layers are indicated, in accordance with some embodiments of the present disclosure.

FIG. 4 provides a reflection comparison of SiNₓ (55 nm), “thicker” SiNₓ (72 nm), and “thinner” SiNₓ (38 nm) as single-layer ARC deposited on the silicon wafers with planar silicon surface (the case of without any ARC (“Bare Si”) is also concluded as a reference), in accordance with some embodiments of the present disclosure.

FIG. 5 provides a reflection comparison of SiNₓ and SiO₂ as single-layer ARC on planar silicon surface (the insert table lists the average reflection from the measurement results), in accordance with some embodiments of the present disclosure.

FIG. 6 provides a reflection comparison of SiNₓ as single-layer ARC (SARC) and MgF₂/ZnS as a double-layer ARC (DARC) on planar silicon surface (the insert table lists the average reflection obtained from the measurement results), in accordance with some embodiments of the present disclosure.

FIG. 7 provides a schematic comparison of reflected light on textured and planar surfaces, in accordance with some embodiments of the present disclosure.

FIGS. 8A-D provides SEM images of textured silicon (100) wafer surface after the anisotropic etching, including (FIG. 8A) top view, (FIG. 8B) top view with sample tilted at −5°, (FIG. 8C) side view with sample tilted at 30°, and (FIG. 8D) side view with sample tilted at 30° by high resolution, in accordance with some embodiments of the present disclosure.

FIG. 9 provides a reflection comparison of single-layer, double-layer, and triple-layer ARC on textured silicon surfaces (the bare planar and textured silicon surfaces are also included), in accordance with some embodiments of the present disclosure.

FIG. 10 provides a reflection comparison of multi-layer ARC and commercial SiPM array as a reference, in accordance with some embodiments of the present disclosure.

FIG. 11 provides a comparison summary of the average reflections of bare Si (no ARC), single-layer, double-layer, and triple-layer ARC on planar and textured surfaces (error bars are included), in accordance with some embodiments of the present disclosure.

FIG. 12 provides a schematic of a conventional front-illuminated SiPM with SiNₓ as single-layer ARC on planar surface. The section highlighted by the dash-line rectangle is enlarged and shown in FIG. 13A.

FIGS. 13A-B provide a schematic comparison of the SiPM cross-sections, including (FIG. 13A) the conventional front-illuminated SiPM with ARC on planar surface, and (FIG. 13B) the back-illuminated SiPM with multi-layer ARC on textured surface, in accordance with some embodiments of the present disclosure.

### DETAILED DESCRIPTION

To facilitate an understanding of the principles and features of the present disclosure, various illustrative embodiments are explained below. The components, steps, and materials described hereinafter as making up various elements of the embodiments disclosed herein are intended to be illustrative and not restrictive. Many suitable components, steps, and materials that would perform the same or similar functions as the components, steps, and materials described herein are intended to be embraced within the scope of the disclosure. Such other components, steps, and materials not described herein can include, but are not limited to, similar components or steps that are developed after development of the embodiments disclosed herein.

In order to reduce the photon losses due to reflection, the approach of antireflection coatings (ARC) is typically used, because it can reduce the photon losses by making use of phase changes and the dependence of the reflectivity on refractive index. In addition to the proper refractive index and film thickness, a low extinction coefficient (K) can also be helpful for the ARC material to avoid a significant photon absorption by the ARC thin-film layer. The ARC materials used in conventional SiPM are thermally grown silicon dioxide (SiO₂) and silicon nitride (SiNₓ) that can be deposited by plasma-enhanced chemical vapor deposition (PECVD) as single-layer ARC (SARC) on planar silicon substrate surface. These conventional photomultipliers (PMs), however, still suffer from high levels of reflection of photons. Accordingly, disclosed herein are embodiments of PMs that include multiple ARCs (e.g., a double-layer ARC (DARC) and triple-layer ARC (TARC)) and/or textured silicon surfaces (e.g., surface includes upright nano-micro pyramids), both of which can reduce the quantity of reflected photons incident on the PM.

For comparison purpose, the performance of the single-layer ARC as well as the bare silicon wafer without ARC on both planar and textured surfaces are also presented below. Further, the back-illuminated SiPM integrated with the multi-layer ARC on textured surface are discussed, as a comparison to the conventional SiPM with ARC on planar surface.

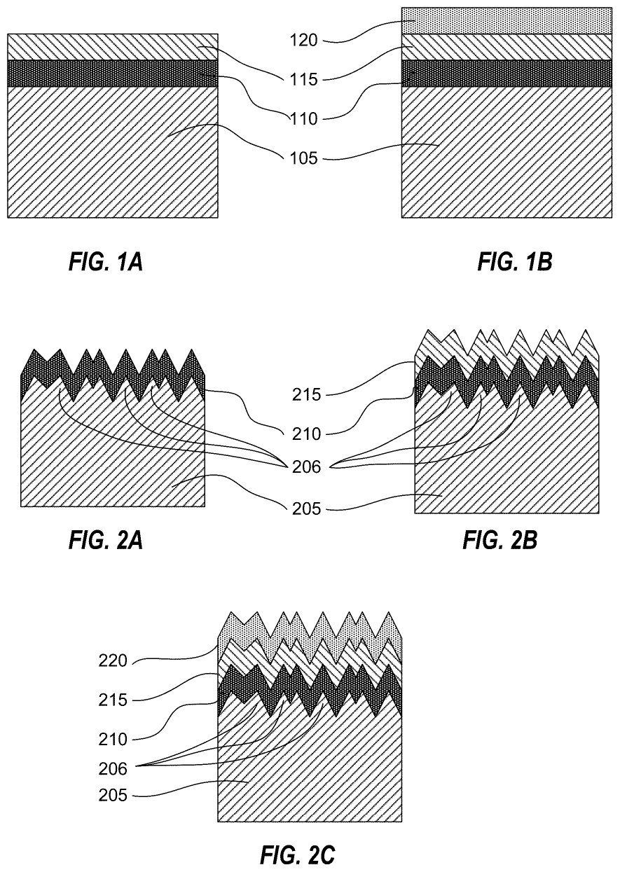

As shown in FIG. 1A, an exemplary embodiment of the present disclosure provides a back-illuminated PM, comprising a silicon substrate 105, a first ARC (also referred to herein as an anti-reflective layer) 110, and a second ARC 115. The silicon substrate 105 can have a top surface. The first ARC 110 can be disposed on the top surface of the silicon substrate 105. The second ARC 115 can be disposed on a top surface of the first ARC 110.

In some embodiments, as shown in FIG. 1B, the PM can further comprise a third ARC 120 disposed on a top surface of the second ARC 115.

Further, in some embodiments, the PM can further comprise additional ARCs (e.g., more than three) disposed above the silicon substrate 105.

The ARCs employed herein can comprise many different materials. In some embodiments, the materials can be selected based on the refractive index of the materials. For example, in some embodiments employing two ARCs, the materials can be selected such that they satisfy (or optimize) the conditions in Equations 3-5 (below). For example, in some embodiments, material of the first ARC 110 can be selected such that its refractive index is approximately 2.33, and the material of the second ARC 115 can be selected such that its refractive index is approximately 1.37. Exemplary compounds sufficiently satisfying these conditions are zinc sulfide (ZnS) for the first ARC 110 and magnesium fluoride (MgF₂) for the second ARC 115.

Similarly, in some embodiments employing three ARCs, the materials can be selected such that they satisfy (or optimize) the conditions in Equations 6-8 (below). For example, in some embodiments, the material of the first ARC 110 can be selected such that its refractive index is approximately 2.49, the material of the second ARC 115 can be selected such that its refractive index is approximately 1.91, the material of the third ARC 120 can be selected such that its refractive index is approximately 1.37. Exemplary compounds sufficiently satisfying these conditions are titanium oxide (TiO₂) for the first ARC 110, hafnium oxide (HfO₂) for the second ARC 115, and magnesium fluoride (MgF₂) for the third ARC 120.

As discussed above, some embodiments of the present disclosure employ a silicon substrate having a “textured” top surface, i.e., the surface can comprise a plurality of protrusions extending upwards from the top surface (see FIGS. 2A-C). This textured silicon surface can be included in embodiments, with one, two, three, or more ARCs, in accordance with various embodiments of the present disclosure.

For example, as shown in FIG. 2A, some embodiments of the present disclosure provides a back-illuminated photomultiplier, comprising a silicon substrate 205 and a first anti-reflective layer 210. The silicon substrate 205 can have a top surface comprising a plurality of protrusions 206 forming a textured surface. As shown in FIG. 2A, the protrusions 206 can be non-uniform in size. The first anti-reflective layer 210 can be disposed on the top surface of the silicon substrate 205.

As shown in FIGS. 2B-C, the textured silicon substrate 205 can also have a second ARC 215 (FIG. 2B) and third ARC 220 (FIG. 2C).

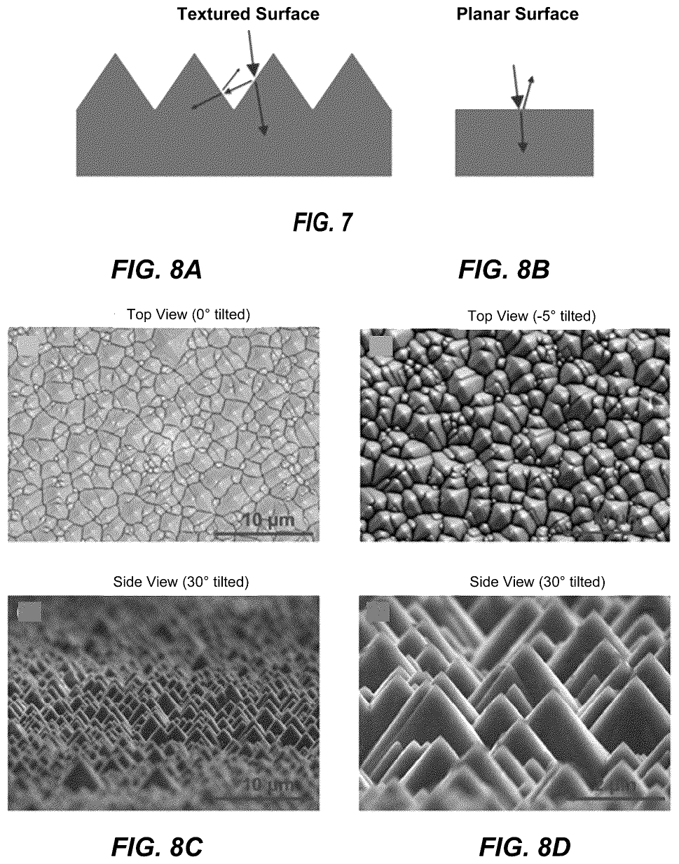

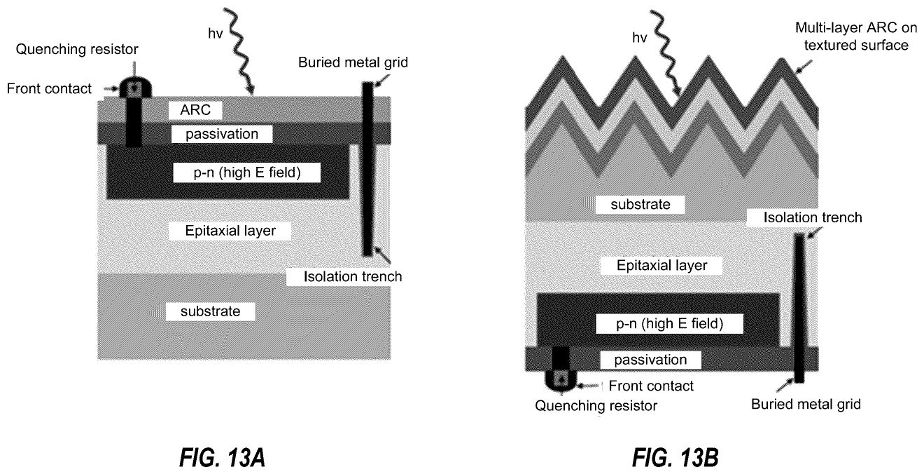

As discussed above, the plurality of protrusions 206 can extend upwards from the top surface as shown in FIG. 2. In some embodiments, as shown in FIG. 2 (see also FIG. 13B), the ARCs 210, 215, 220 can conform to the textured surface of the silicon substrate 205. Protrusions 206 can have many different shapes to allow photons that are initially reflected from the top surface to be incident on the surface again (see FIG. 7), thus giving reflected photons a second chance to be absorbed into the silicon substrate 205. In some embodiments, as shown in FIG. 2, the protrusions 206 can have a pyramid shape. Additionally, as also shown in FIG. 2 (see also FIGS. 8A-D), the protrusions 206 can be non-uniform in size, which can further limit the number of photons reflected (i.e., not ultimately absorbed) by the silicon substrate 205.

The textured surface (plurality of protrusions) can be formed many different ways known in the art, including, but not limited to, anisotropic etching.

As discussed below and shown in FIGS. 6 and 9-11, the back-illuminated PMs of the present disclosure having a textured silicon substrate surface and/or multiple ARCs can reflect substantially less photons across a wavelength of 200-800 nm, as compared to conventional PMs. For example, in some embodiments, a PM having a double ARC without a textured surface can reflect no more than 25%, no more than 20%, no more than 18%, or no more than 15% of photons incident on the PM across the wavelength range of 200-800 nm. In some embodiments, a PM having a triple ARC without a textured surface can reflect no more than 25%, no more than 20%, no more than 15%, or no more than 13% of photons incident on the PM across the wavelength range of 200-800 nm. In some embodiments, a PM having a single ARC with a textured surface can reflect no more than 15%, no more than 10%, or no more than 7% of photons incident on the PM across the wavelength range of 200-800 nm. In some embodiments, a PM having a double ARC with a textured surface can reflect no more than 15%, no more than 10%, no more than 7%, or no more than 5% of photons incident on the PM across the wavelength range of 200-800 nm. In some embodiments, a PM having a triple ARC with a textured surface can reflect no more than 15%, no more than 10%, no more than 5%, or no more than 3% of photons incident on the PM across the wavelength range of 200-800 nm.

### EXAMPLES

The discussion below provides certain exemplary embodiments of the present disclosure and further includes a technical explanation as to the operation of certain embodiments. The following discussion, however, is provided for exemplary and explanatory purposes only and should not be construed as limiting the scope of the present disclosure.

### Single-Layer Antireflection Coating

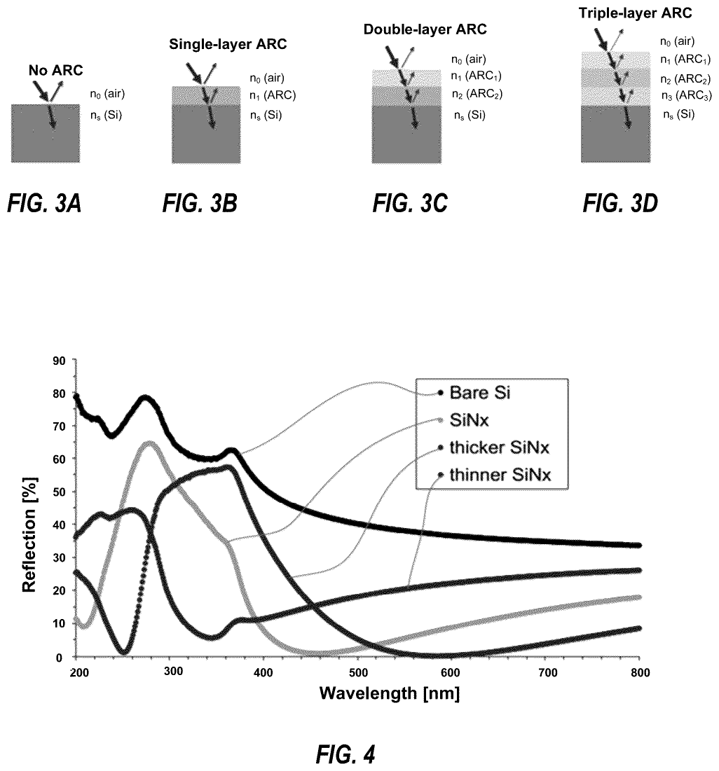

According to the theory of quarter-wave dielectric layer, the reflection of incident beam of light reflected from the surface of a single-layer ARC deposited on a substrate material has its minimum value when:

$${n}_{1} = \sqrt{{n}_{0} {n}_{s}} \qquad Equation 1$$

$${n}_{1} {d}_{1} = {λ}_{0} / 4 \qquad Equation 2$$

where n₀, n₁, and nₛ represent the refractive indices of medium (air herein), ARC material, and absorption substrate material (silicon in this work), respectively. d1 is the thickness of ARC layer, and λ0 is the wavelength of incident light with minimum reflection. For a SiPM in air (n0=1.0, and nₛ=3.8), the optimum refractive index of single-layer ARC is n₁≈1.9. Note that the specific refractive index values given herein are measured at the wavelength of 632 nm. Therefore, the conventional single-layer ARC material SiNx was applied as a reference due to its refractive index of 1.96 close to the optimum value, and the SiO2 was also included as a comparison because it is typically used as a surface passivation material as well as an ARC material at the same time for the early SiPM studies. FIG. 3B shows the schematic of single-layer ARC on silicon wafers in this study, the case of no AR is also included (FIG. 3A).

FIG. 4 shows that the 55-nm SiNₓ deposited on planar silicon surface as a single-layer ARC can minimize the reflection close to zero at the wavelength of 450 nm, which is in good agreement with the condition Eqs. 1-2. The “thicker” SiNₓ (72 nm) shifts the reflection curve to higher wavelength with the minimum reflection close to zero at around 600 nm, while the “thinner” SiNₓ (38 nm) results in the minimum reflection of still over 5% at about 340 nm, suggesting the thickness of 38 nm is too thin for SiNₓ as a single-layer ARC. It is also indicated in FIG. 4 that the average reflection of all studied SiNₓ films as single-layer ARC measured in the spectrum of 200-800 nm are all over 15%, although the minimum reflection can be reduced to zero at certain wavelength by changing the SiNₓ thickness.

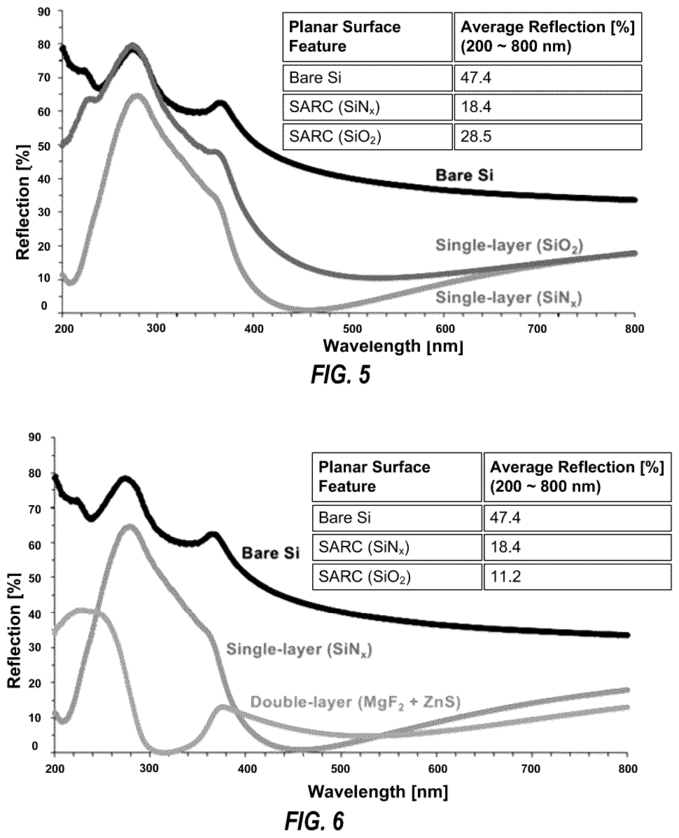

Although SiO₂ demonstrates a better surface passivation function than SiNₓ due to lower interface defect density, and the earlier SiPM studies use it as a surface passivation layer as well as a single-layer ARC, FIG. 5 clearly shows that SiO₂ has inferior antireflection performance over the studied spectrum. Compared to the case of without any ARC (bare silicon surface), SiO₂ can reduce the reflection shown in FIG. 5, and the average reflection can be reduced from 47.4% to 28.5%. However, it can still be much higher than that of SiNₓ (18.4%), as summarized by the insert table in FIG. 5. Therefore, FIG. 5 reveals that SiO₂ may not be a proper ARC material, and SiNₓ as a single-layer ARC may not be sufficient to reduce photon losses for high-performance next-generation SiPM devices.

### Multi-Layer ARC: Double-Layer ARC and Triple-Layer ARC

Although a single-layer ARC can minimize the reflection down to zero at a specific wavelength when it meets the conditions as given by Eqs. 1 and 2, its reflections at other wavelengths can still be high because its refractive index is wavelength-dependent. Therefore, to reduce the reflection over a wide spectrum of 200-800 nm, some embodiments of the present disclosure can include multi-layer ARCs, including double-layer ARC or triple-layer ARC, as shown in FIGS. 3C-D. The multi-layer ARC feature can decrease the reflection at the surface because of the interference of the reflected light from each interface. The transfer matrix method (TMM) in addition to the theory of quarter-wave dielectric layers were applied to determine exemplary multi-layer ARC materials and their thicknesses.

For the double-layer ARC feature, to minimize the average reflection over a wide spectrum, the selected ARC materials can meet the conditions:

$${n}_{1} = \sqrt[3]{{n}_{0}^{2} \cdot {n}_{s}} \qquad Equation 3$$

$${n}_{2} = \sqrt[3]{{n}_{0} \cdot {n}_{s}^{2}} \qquad Equation 4$$

$${d}_{j} = \frac{{λ}_{0}}{4 {n}_{j}} \qquad Equation 5$$

where n₀, n₁, n₂, and nₛ represent the refractive dices of each layer as shown in FIG. 3C, and dj (j=1, and 2) is the thickness of ARC layer. Therefore, according to the conditions (3) and (4), magnesium fluoride (MgF₂, n₁=1.37) and zinc sulfide (ZnS, n2=2.33) were selected as constituent layers of the double-layer ARC discussed below.

Similarly, for the triple-layer ARC feature, the following conditions of refractive indices of the selected ARC materials can be met to minimize the average reflection over a wide spectrum:

$${n}_{1} = \sqrt[4]{{n}_{0}^{3} \cdot {n}_{s}} \qquad Equation 6$$

$${n}_{2} = \sqrt{{n}_{0} \cdot {n}_{s}} \qquad Equation 7$$

$${n}_{3} = \sqrt[4]{{n}_{0} \cdot {n}_{s}^{3}} \qquad Equation 8$$

where n₀, n₁, n₂, n₃, and nₛ are the refractive indices of each layer as shown in FIG. 3D. The thickness of each layer dj (j=1, 2, and 3) can be determined by Eq. (5). So, below investigated MgF₂ (n1=1.37), HfO₂ (n₂=1.91), and TiO₂ (n₃=2.49) for the triple-layer ARC feature.

FIG. 6 shows that double-layer ARC can reduce the reflection for most wavelengths, compared to SiNₓ as single-layer ARC, especially in the ultraviolet (UV) range, with the minimum reflection close to zero at round 320 nm. Its resulted average reflection also decreases to 11.2%. However, its reflection at wavelength below 280 nm is still high (over 15%), and even higher than that of SiNₓ at below 250 nm. Therefore, this work develops the textured surface in combination with multi-layer ARC features to enhance the light trapping and hence reduce the photon losses.

Textured Surface with Upright Random Nano-Micro Pyramids Formed by Anisotropic Etching

To enhance the light trapping on silicon wafer, texturing the wafer surface by an anisotropic etching to obtain upright random nano-micro pyramidal structures is an effective approach to reduce the surface reflection. As shown FIG. 7, compared to the planar surface where the light reflected from the surface is completely lost, the textured surface can allow the light reflected from the side of one of pyramids to be reflected downward, and then getting a second chance of being absorbed into the silicon bulk. The formation of these random arrays of ideal {111} faceted upright pyramids on the etched surface can be driven by the anisotropic nature of the chemical etchant, that is, the etch rate in the <100> direction of single crystalline silicon can be several times greater than that in the <111> direction. The higher etch rate in the <100> direction can be because the {100} surface can require the lower activation energy to remove an atom than the {111} surface. This is because the {100} surface can only need to break two back bonds rather than three ones in the case of {111} surface. Note that each atom of Si {111} surface can have three back bonds and one dangling bond, but each atom of {100} surface can have two back bonds and two dangling ones. Therefore, the upright pyramids can be formed by the intersection of (100) and (111) planes as the consequence of anisotropic etching of silicon (100) substrate due to the slowest etching rate of {111} crystallographic planes.

FIG. 8 displays the surface morphology of etched silicon (100) wafers by scanning electron microscope (SEM) images taken on the textured surface after the anisotropic etching. The appearance of the upright random nano-micro pyramids can be clearly seen from these SEM images. The sizes of these pyramids are random, in the range of a few hundreds of nanometers to a couple of microns. These upright pyramids can be formed due to the anisotropic etching of silicon (100) substrate, which are bounded by {111} crystallographic planes because of the slowest etching rate of {111} planes. The image in FIG. 8A is obtained from the top view, showing the pyramid tips as shining points and the pyramid base borders as black lines, while the resulted image in FIG. 8B gives a more straightforward view after tilting the sample at −5°. From the side view and tilting the sample at 30°, image in FIG. 8C shows an art-like overview of resulted upright pyramids, and image in FIG. 8D gives a closer look after increasing the SEM resolution.

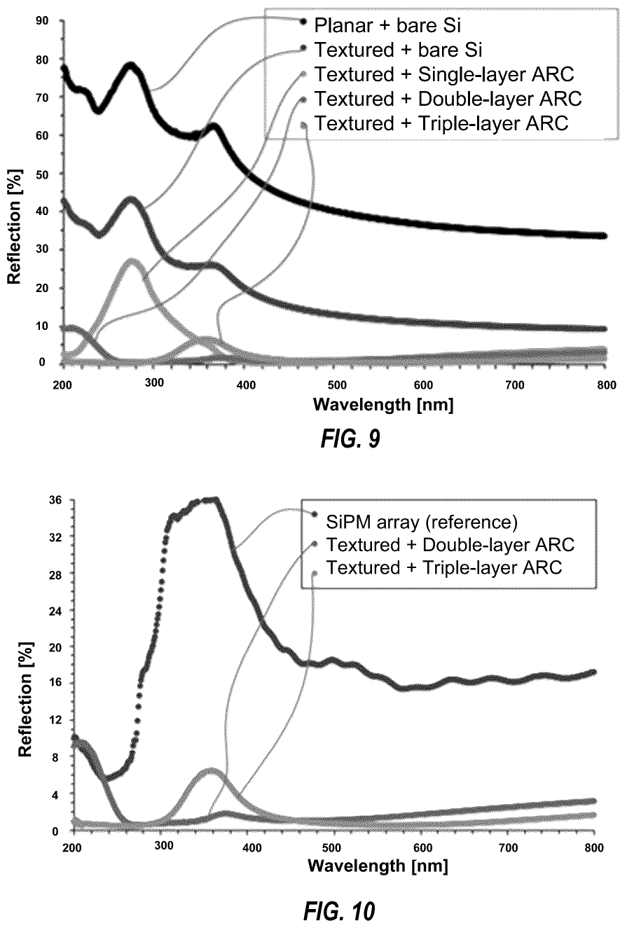

As shown in FIG. 9, the textured bare surface can have much lower reflection than the planar bare surface over the entire spectrum, because it allows the light reflected from the side of pyramids to be reflected downward and hence get a second chance of being absorbed into silicon, as demonstrated in FIG. 7. This leads to its average reflection of only 18.6%, a dramatical decrease from that of the planar surface (47.4%). FIG. 9 also indicates that the reflection reduction between the textured and planar surfaces can be almost similar for all wavelengths because of the same light trapping mechanism regardless of the wavelength. To further reduce the reflection, various ARC dielectric stacks can be deposited on the textured surface to combine the antireflection benefits of both the textured surface and the ARC feature.

### Multi-Layer ARC on Textured Surface

It is shown in FIGS. 9-10 that the single-layer ARC (SiNₓ) on textured surface can provide a dramatical decrease in reflection, compared to the bare textured surface. Its reflection is close to zero for the wavelength above 400 nm, while it bumps up in the UV range, and peaks at over 27% around 275 nm. These result in its average reflection of 5.0% on textured surface, an effective improvement from the same ARC feature on planar surface (18.4%) shown in FIGS. 5-6.

Having the reflection as low as the single-layer ARC for the wide spectrum from blue light to red light, the double-layer ARC (MgF₂/ZnS) on textured surface can cut down significantly the reflection for the UV light, as shown in FIGS. 9-10. However, its reflection can gradually increase at wavelength below 260 nm, and saturates at approximately 9% around 200 nm. These can lead to a very low average reflection of 2.3%, compared to 11.2% for the same double-layer ARC feature on planar surface listed in FIG. 6, a very impressive enhancement in antireflection.

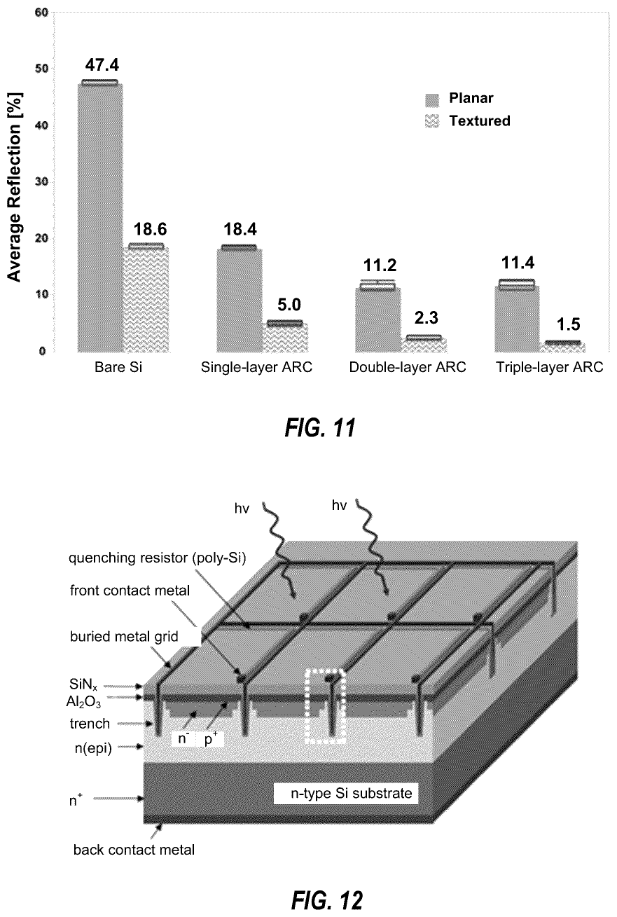

FIGS. 9-10 display that the triple-layer ARC (MgF₂/HfO₂/TiO₂) on textured surface can reduce the reflection down to less than 1% for the wavelengths below 260 nm, which is a very promising enhancement, compared to the double-layer ARC feature. Its reflection also can be marginally lower at the wavelength above 500 nm than the double-layer ARC, but bumps up in the range of 300-420 nm, and peaks at 6.5% around 360 nm. These can result in an average reflection of 1.5%, the lowest among the studied antireflection features in this work. FIG. 11 summarizes the average reflections of single/double/triple-layer ARC on planar and textured surfaces, as well as the bare planar and textured surfaces without ARC. It clearly displays that the ARC features on textured surfaces can have lower average reflection than their counterparts on planar surfaces. In addition, the multi-layer ARC features can reduce the average reflection more than the single-layer ARC regardless of the silicon wafer surface tomography, either planar or textured, as shown in FIG. 11.

When SiPM is coupled with a scintillator for radiation detection applications, it can be important for the sensitive wavelength of SiPM to match with the emission wavelength of scintillators. For example, barium fluoride (BaF₂) scintillators are among the fastest scintillators with sub-nanosecond decay time for emitted “fast” pulses at wavelength of 220 nm, and widely used in the applications of time-of-flight measurement, PET, nuclear and high energy physics. Therefore, to detect these “fast” pulses emitted from BaF₂ scintillators, the triple-layer ARC on textured surface can be a better feature than the double-layer ARC, because it can enable lower reflection at wavelength range of 220 nm shown in FIG. 10, and hence potentially higher PDE. While detecting the photons with wavelength in the range of 300-420 nm, i.e., emitted from cesium fluoride (CsF), cerium fluoride (CeF₃), and yttrium orthoaluminate (YAlO₃) scintillators, the double-layer ARC on textured surface may be a competitive option, but the triple-layer ARC on textured surface can be still a better feature for detecting photons with wavelength over 460 nm, i.e., coming from Y₃Al₅O₁₂ and CsI:Tl scintillators. Below, there is additional discussion about the back-illuminated SiPM with the multi-layer ARC on textured surface.

### Discussion

FIG. 12 shows the schematic of conventional front-illuminated SiPM with SiNₓ as single-layer ARC on planar surface where photons are incident. As a solid-state photodetector, SiPM is segmented in tiny Geiger-mode Avalanche Photodiodes (GM-APD), also called microcells. The cross-section of a microcell of this SiPM structure is enlarged and shown in FIG. 13A. The pn-junction of microcell is formed on the top of epitaxial layer that is grown on the n-type Si wafer substrate to create a high-field region for the Geiger-mode avalanche events via a sufficient bias voltage. The Al₂O₃ thin film can act as an excellent passivation layer to passivate the surface defects (i.e., dangling bonds) to suppress the carrier recombination by its low interface defect density and built-in negative fixed charges at the interface to shield the electron carriers. The front contact metal can be connected to the positively-doped emitter layer (p⁺) and the quenching resistor that is used to turn off the avalanche current to reduce the operating voltage down to below the breakdown voltage, so that the microcell can be restored to its initial status and get ready to detect a new event. Through the quenching resistors, each microcell can be connected in parallel to the front buried metal grid. The isolation trenches between microcells can be introduced to minimize the optical cross-talk effect that is one of noise sources, but it can reduce the total active areas and hence the FF.

In addition, the guard ring structure at the edge area with lower doping level (p⁻) than the active area (p⁺) can prevent an edge premature breakdown, but induces a reduction in the active area. As a consequence, this conventional front-illuminated SiPM structure can have not only a high photon reflection due to the ARC on planar surface but also a limited FF due to the dead areas (i.e., quenching resistor, front contact mental, isolation trench, and guard ring) on the detector side where the photons are incident, which can limits quantum efficiency (QE) and hence PDE. Therefore, the back-illuminated SiPM with multi-layer ARC on textured surface was investigated.

FIG. 13 compares the microcell cross-sections of the conventional front-illuminated SiPM with ARC on planar surface (FIG. 13A) and the back-illuminated SiPM with multi-layer ARC on textured surface that is disclosed herein (FIG. 13B). For the conventional front-illuminated SiPM, the incoming photons are incident on the planar surface coated by ARC, being on the same side as the avalanche regions (high electrical field regions). In contrast, for the back-illuminated SiPM, the incoming photons fall on the detector side opposite to the avalanche regions. The multilayer ARC on textured surface disclosed herein can be designed on the detector side of back-illuminated SiPM shown in FIG. 13B, directly facing the incoming photons. As shown in FIG. 10, the multi-layer ARC on textured surface can have a much lower reflection over the entire spectrum than the SiPM array that has the conventional front-illuminated structure with ARC on planar surface. Note that this SiPM array is SensL J-Series sensors (635J1) with microcell size of 35×35 μm², FF of 75%, the maximum PDE of 50% at 420 nm, dark count rate of 150 kHz/mm², and gain of 6.3×10⁶. The resulted average reflection of this SiPM array is 18.9%, much higher than those of the multi-layer ARC on textured surface, 2.3% for the double-layer ARC and 1.5% for the triple-layer ARC. So, applying the multi-layer ARC on textured surface to the back-illuminated SiPM can reduce dramatically its reflection and hence potentially boost its PDE and QE that can be defined as the probability for an incident photo to generate a primary electron-hole pair and subsequent collection of photogenerated carriers in the active area of the SiPM device.

In addition, as the dead areas (including quenching resistor, isolation trench, and guard ring) are relocated to the microcell's bottom side, the back-illuminated SiPM structure can have more active areas on the top side where photons are incident, which can lead to a much higher FF, compared to the conventional front-illuminated structure that typically limits the FF to 80% or even much lower for smaller microcell sizes. Combining the high FF (potentially close to 100%) and the low reflection as described above, the back-illuminated SiPM structure with multi-layer ARC on textured surface shown in FIG. 13B can improve the PDE to a very promising level.

It is demonstrated herein that a multi-layer ARC on textured silicon surface with upright random nano-micro pyramids can dramatically reduce the reflection over a wide spectrum, compared to the conventional single-layer ARC on planar surface for SiPM. On the planar silicon surface, SiNₓ as the conventional single-layer ARC can have a better antireflection performance than SiO2 due to its optimum refractive index, and can minimize the reflection down close to zero at specific wavelengths for the optimum film thickness, but its average reflection of 18.4% can be higher than that of the multi-layer ARC (about 11%). The textured surface can be formed by the anisotropic etching of silicon (100) substrate in alkaline solution due to the slowest etching rate of {111} crystallographic planes, and lead to significantly lower reflection than the planar surface regardless of the wavelength, resulting in the average reflection of 18.6% vs 47.4%. This can be due to its powerful light trapping feature that allows the light reflected from the side of pyramids to be reflected downward and get a second chance of being coupled into silicon. The combined feature of the multi-layer ARC deposited on the textured surface can empower the light trapping performance even further by reducing the average reflection down to 2.3% for the double-layer ARC (MgF2/ZnS), and 1.5% for the triple-layer ARC (MgF2/HfO2/TiO2), which can be lower than that of the single-layer ARC on textured surface (5.0%).

Compared to the conventional front-illuminated SensL SiPM array with ARC on planar surface that have an average reflection of 18.9%, a FF of 75%, and a state-of-the-art PDE of 50%, an exemplary back-illuminated SiPM with the multi-layer ARC on textured surface can increase the PDE to a very promising level by the ultra-low average reflection of 1.5% and the much higher FF (potentially approach to 100%) due to the elimination of the dead areas from the detector side. Benefiting from its reflection close to zero for the wavelength range of 200-300 nm, the studied feature of the multi-layer ARC on textured surface can enable the back-illuminated SiPM to effectively detect the “fast” pulses with sub-nanosecond decay time at wavelength of 220 nm emitted from one of the fastest scintillators BaF₂, which paves a way to facilitate its broad applications, such as time-of-flight measurement, PET, scintillation light detection in ionizing radiation, nuclear and high energy physics.

### Methods

The silicon wafers disclosed herein were polished float-zone 4-inch n-type (100) wafers with thickness of 280 m. The wafers were processed in a 5% hydrogen fluoride (HF) solution prior to depositing ARC thin films. The SiNₓ dielectric thin films were deposited by PECVD at 250° C. with precursors of nitrogen, silane, and ammonia. Three different thicknesses of SiNₓ films were compared, including a designated thickness of 55 nm in order to detect the photons emitted from conventional scintillators with wavelength around 450 nm, a “thicker” film of 72 nm, and a “thinner” one of 38 nm. The 78-nm SiO₂ films (refractive index nSiO₂=1.46) used to compare SiNₓ in the single-layer ARC feature were also deposited by PECVD at 250° C. with precursors of nitrogen, silane, and nitrous oxide. For the multi-layer ARC features, zinc sulphide (ZnS, refractive index nZnS=2.20) and magnesium fluoride (MgF₂, refractive index nMgF₂=1.37) thin films were grown by a thermal-evaporator at the voltages of 15 V and 10 V and the deposition rate of 2 Å/s, with the film thicknesses of 48 nm and 77 nm. Titanium oxide (TiO₂, refractive index nTiO₂=2.49) and hafnium oxide (HfO₂, refractive index nHfO₂=1.91) thin films were deposited by an E-beam evaporator at the deposition rate of 0.5 Å/s. The film thicknesses of triple-layer ARC were 42, 55, and 77 nm for TiO₂, HfO₂, MgF2, respectively. Note that the physical vapor deposition (PVD) techniques disclosed herein are the thermal-evaporator and the E-beam evaporator, which are less conformal than the chemical vapor deposition (CVD) or the atomic-layer deposition (ALD) techniques. However, because the pyramids with feature base angle of about 540 formed on the silicon wafer surface can be in the scale of one micron while the ARC thickness in this study was in the scale of 100 nm, the applied deposition technique would have negligible impact on the reflection measurement results. After the ARC depositions, the wafers were characterized by a Cary 5000 UV-Vis/NIR spectrophotometer to measure the total reflectance (specular and scattering) in the wide spectrum of 200-800 nm, which is enabled by using a combination of a tungsten halogen and deuterium arc light source to illuminate the samples.

The anisotropic etching was performed in the 3% (volume ratio) potassium hydroxide (KOH) alkaline and 4% isopropyl alcohol (IPA) and deionized (DI) water mixture solutions at a high temperature of 80° C. for 20 min. After the texturing, the wafers were cleaned in a 5% HF solution. Note that all the wet chemical processing and the thin film depositions were performed in the specialized class 100 cleanrooms to avoid contaminations. This work used the scanning electron microscope (SEM) technique at 5 kV to characterize the surface features after the texturing process.

It is to be understood that the embodiments and claims disclosed herein are not limited in their application to the details of construction and arrangement of the components set forth in the description and illustrated in the drawings. Rather, the description and the drawings provide examples of the embodiments envisioned. The embodiments and claims disclosed herein are further capable of other embodiments and of being practiced and carried out in various ways. Also, it is to be understood that the phraseology and terminology employed herein are for the purposes of description and should not be regarded as limiting the claims.

Accordingly, those skilled in the art will appreciate that the conception upon which the application and claims are based may be readily utilized as a basis for the design of other structures, methods, and systems for carrying out the several purposes of the embodiments and claims presented in this application. It is important, therefore, that the claims be regarded as including such equivalent constructions.

Furthermore, the purpose of the foregoing Abstract is to enable the United States Patent and Trademark Office and the public generally, and especially including the practitioners in the art who are not familiar with patent and legal terms or phraseology, to determine quickly from a cursory inspection the nature and essence of the technical disclosure of the application. The Abstract is neither intended to define the claims of the application, nor is it intended to be limiting to the scope of the claims in any way.

What is claimed is:

1. A back-illuminated photomultiplier, comprising:
a silicon substrate having a top surface;
a first anti-reflective layer disposed on the top surface of the silicon substrate; and
a second anti-reflective layer disposed on a top surface of the first anti-reflective layer.

2. The back-illuminated photomultiplier of claim 1, wherein one of the first and second anti-reflective layers comprises MgF₂.

3. The back-illuminated photomultiplier of claim 2, wherein one of the first and second anti-reflective layers comprises ZnS.

4. The back-illuminated photomultiplier of claim 1, further comprising a third anti-reflective layer disposed on a top surface of the second anti-reflective layer.

5. The back-illuminated photomultiplier of claim 4, wherein one of the first, second, and third anti-reflective layers comprises MgF₂.

6. The back-illuminated photomultiplier of claim 5, wherein one of the first, second, and third anti-reflective layers comprises HfO₂.

7. The back-illuminated photomultiplier of claim 6, wherein one of the first, second, and third anti-reflective layers comprises TiO₂.

8. The back-illuminated photomultiplier of claim 1, wherein the top surface of the silicon substrate comprises a plurality of protrusions extending upwards from the top surface.

9. The back-illuminated photomultiplier of claim 8, wherein the plurality of protrusions are pyramid-shaped.

10. The back-illuminated photomultiplier of claim 9, wherein the plurality of protrusions have non-uniform sizes.

11. The back-illuminated photomultiplier of claim 1, wherein the photomultiplier reflects less than 15% of photons incident on the photomultiplier averaged across a wavelength range of 200 nm-800 nm.

12. The back-illuminated photomultiplier of claim 4, wherein the photomultiplier reflects less than 13% of photons incident on the photomultiplier averaged across a wavelength range of 200 nm-800 nm.

13. The back-illuminated photomultiplier of claim 8, wherein the photomultiplier reflects less than 5% of photons incident on the photomultiplier averaged across a wavelength range of 200 nm-800 nm.

14. The back-illuminated photomultiplier of claim 4, wherein the top surface of the silicon substrate comprises a plurality of protrusions extending upwards from the top surface, and wherein the photomultiplier reflects less than 3% of photons incident on the photomultiplier averaged across a wavelength range of 200 nm-800 nm.

15. A back-illuminated photomultiplier, comprising:
a silicon substrate having a top surface, the top surface comprising a plurality of non-uniform protrusions; and
a first anti-reflective layer disposed on the top surface of the silicon substrate.

16. The back-illuminated photomultiplier of claim 15, wherein the photomultiplier reflects less than 7% of photons incident on the photomultiplier averaged across a wavelength range of 200 nm-800 nm.

17. The back-illuminated photomultiplier of claim 15, further comprising a second anti-reflective layer disposed on the top surface of the first anti-reflective layer.

18. The back-illuminated photomultiplier of claim 17, wherein the photomultiplier reflects less than 5% of photons incident on the photomultiplier averaged across a wavelength range of 200 nm-800 nm.

19. The back-illuminated photomultiplier of claim 17, further comprising a third anti-reflective layer disposed on the top surface of the second anti-reflective layer.

20. The back-illuminated photomultiplier of claim 19, wherein the photomultiplier reflects less than 3% of photons incident on the photomultiplier averaged across a wavelength range of 200 nm-800 nm.
